(19) United States
(12) Patent Application Publication
(10) Pub. No.: US 2024/0282599 A1
(43) Pub. Date: Aug. 22, 2024

(54) LIQUID CHEMICAL RECYCLE SYSTEM, LIQUID CHEMICAL SUPPLY SYSTEM, AND METHOD OF MANUFACTURING SEMICONDUCTOR DEVICE USING THE LIQUID CHEMICAL RECYCLE SYSTEM

(71) Applicant: Samsung Electronics Co., Ltd., Suwon-si (KR)

(72) Inventors: Jinho Yoo, Suwon-si (KR); Sughyung Kwon, Suwon-si (KR); Nackhoon Kim, Suwon-si (KR); Youngkwang Myoung, Suwon-si (KR); Sanghun Park, Suwon-si (KR)

(21) Appl. No.: 18/541,635

(22) Filed: Dec. 15, 2023

(30) Foreign Application Priority Data
Feb. 17, 2023 (KR) 10-2023-0021658
Apr. 28, 2023 (KR) 10-2023-0056640

(51) Int. Cl. H01L 21/67; H01L 21/311

(52) U.S. Cl. CPC H01L 21/6708; H01L 21/31111

(57) ABSTRACT

A liquid chemical recycle system includes a liquid chemical supply tank, a processing tank, a recovery line, a recycle tank, and a circulation line, wherein the processing tank includes a third bowl, a second bowl, and a first bowl.

### CROSS-REFERENCE TO RELATED APPLICATION

This application is based on and claims priority under 35 U.S.C. § 119 to Korean Patent Application Nos. 10-2023-0021658 and 10-2023-0056640, respectively, filed on Feb. 17, 2023 and Apr. 28, 2023, in the Korean Intellectual Property Office, the disclosures of which are incorporated by reference herein in their entireties.

### BACKGROUND

Aspects of the inventive concept relate to a liquid chemical recycle system, a liquid chemical supply system, and a method of manufacturing a semiconductor device using the liquid chemical recycle system. More specifically, aspects of the inventive concept relate to a liquid chemical recycle system using a high-concentration hydrofluoric acid liquid chemical, a liquid chemical supply system, and a method of manufacturing a semiconductor device using the liquid chemical recycle system.

In general, according to the high density, high integration, and high performance of semiconductor devices, circuit patterns are rapidly miniaturized, and thus, contaminants such as particles, organic contaminants, and metal contaminants remaining on the surface of a substrate have a significant effect on device characteristics and production yield. For this reason, a cleaning process of removing various contaminants attached to the surface of the substrate has been very important in a semiconductor manufacturing process, and a process of cleaning the substrate is performed at stages before and after each unit process of manufacturing a semiconductor.

Cleaning methods currently used in the semiconductor manufacturing process are largely divided into dry cleaning and wet cleaning. Wet cleaning is divided into a bath type method in which a substrate is immersed in a liquid chemical and contaminants are removed by chemical dissolution, etc., and a spin type method in which a substrate is placed on a spin chuck and contaminants are removed by supplying a liquid chemical to the surface of the substrate while rotating the substrate.

In order to manufacture a semiconductor device, a multi-layered thin film is formed on a semiconductor substrate, and etching and cleaning processes are generally adopted as essential for forming a thin film. In the etching and cleaning processes, a thin film such as a nitride film deposited on the back side of the substrate and particles act as impurities in a subsequent process. Impurities such as an unnecessary thin film on the back side of the substrate are removed by using a substrate cleaning device.

### SUMMARY

Aspects of the inventive concept provide a high-concentration hydrofluoric acid liquid chemical recycle system capable of optimizing a process stability while reducing the amount of waste water.

Aspects of the inventive concept also provide a high-concentration hydrofluoric acid chemical recycle system capable of improving a process efficiency and reducing the amount of liquid chemical raw materials used.

In addition, the problem to be solved by aspects of the inventive concept are not limited to the above-mentioned problems, and other problems may be clearly understood by those skilled in the art from the description below.

According to an aspect of the inventive concept, there is provided a liquid chemical recycle system.

The liquid chemical recycle system includes a liquid chemical supply tank storing and configured to supply a liquid chemical, a processing tank configured to inject the liquid chemical supplied from the liquid chemical supply tank through an injection nozzle to perform an etching process on a substrate disposed on a substrate support, a recovery line configured to recover the liquid chemical discharged from the processing tank, a recycle tank connected to the recovery line, and a circulation line configured to connect the recycle tank to the injection nozzle, wherein the processing tank includes a third bowl including a ring-shaped side wall formed in a direction parallel to a side surface of the processing tank inside the processing tank, a second bowl including a ring-shaped side wall formed in a direction parallel to a side surface of the third bowl inside the third bowl, and a first bowl including a ring-shaped side wall formed in a direction parallel to a side surface of the second bowl inside the second bowl.

According to another aspect of the inventive concept, there is provided a liquid chemical supply system.

The liquid chemical supply system includes a liquid chemical supply tank storing and configured to supply a liquid chemical, a processing tank configured to perform an etching process on a substrate disposed on a substrate support, a pedestal disposed in parallel to the substrate support at a level lower than the substrate support inside the processing tank, a recycle tank storing a remaining liquid chemical discharged from the processing tank during the etching process and configured to filter impurities through an internal circulation system, and a circulation line configured to connect the recycle tank and the processing tank, wherein the remaining liquid chemical is discharged from the processing tank through a first pipe of the processing tank to a recovery line configured to connect the processing tank and the recycle tank and re-supplied to the processing tank through the circulation line.

According to another aspect of the inventive concept, there is provided a method of manufacturing a semiconductor device.

The method includes providing a substrate including a first thin film, and removing at least a part of the first thin film by using a wet etching process on the substrate, wherein the wet etching process utilizes a liquid chemical recycle system, the liquid chemical recycle system includes a liquid chemical supply tank storing and configured to supply a liquid chemical, a processing tank configured to inject the liquid chemical supplied from the liquid chemical supply tank through an injection nozzle to perform an etching process on a substrate disposed on a substrate support, a recovery line configured to recover the liquid chemical discharged from the processing tank, a recycle tank connected to the recovery line and configured to filter impurities through a circulation system, and a circulation line configured to connect the recycle tank to the injection nozzle, and the processing tank includes a third bowl including a ring-shaped side wall formed in a direction parallel to a side surface of the processing tank inside the processing tank, a second bowl including a ring-shaped side wall formed in a direction parallel to a side surface of the third bowl inside the third bowl, and a first bowl including a ring-shaped side wall formed in a direction parallel to a side surface of the second bowl inside the second bowl.

### BRIEF DESCRIPTION OF THE DRAWINGS

Embodiments will be more clearly understood from the following detailed description taken in conjunction with the accompanying drawings in which:

FIG. 1 is a diagram showing a schematic configuration of a liquid chemical recycle system according to aspects of the inventive concept;

FIG. 2 is a cross-sectional view showing an internal configuration of a processing tank shown in FIG. 1;

FIGS. 3A to 3C are diagrams schematically showing the principle of operation of a three-stage bowl disposed inside a processing tank; and

FIG. 4 is a flowchart illustrating an operation procedure of a liquid chemical recycle system according to aspects of the inventive concept.

### DETAILED DESCRIPTION OF THE EMBODIMENTS

Hereinafter, embodiments are described in detail with reference to the accompanying drawings. Like reference numerals in the drawings denote like elements, and thus their repetitive description is omitted.

The embodiments may allow various kinds of change or modification and various changes in form, and specific embodiments will be illustrated in drawings and described in detail in the detailed description. However, it should be understood that the specific embodiments do not limit aspects of the inventive concept to a specific disclosing form but include every modified, equivalent, or replaced one that is within the disclosed spirit and technical scope. In the description of the embodiments, when it is determined that a specific description of relevant well-known features may obscure the description of particular aspects of the inventive concept, a detailed description thereof is omitted.

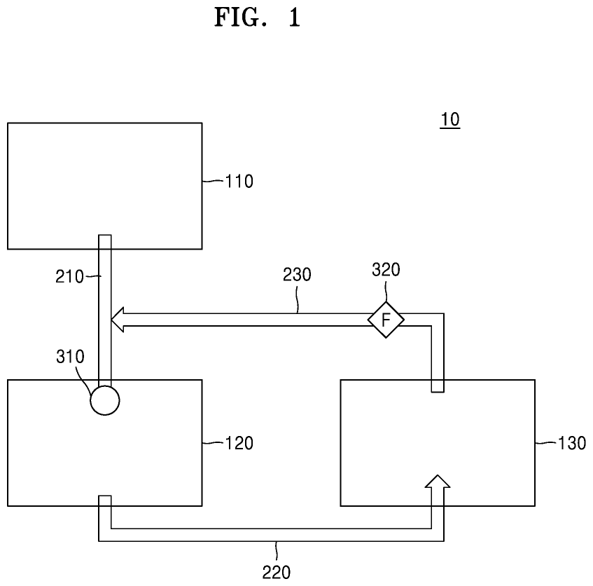

FIG. 1 is a diagram showing a schematic configuration of a liquid chemical recycle system according to aspects of the inventive concept. In the following, in order to clarify the position relationship, the X-axis, Y-axis, and Z-axis that are orthogonal to each other are defined, and the positive Z-axis direction is the vertical upward direction.

As shown in FIG. 1, a liquid chemical recycle system 10 according to an embodiment includes a liquid chemical supply tank 110, a processing tank 120, a recycle tank 130, a liquid chemical supply pipe 210, a recovery line 220, a circulation line 230, an injection nozzle 310, and a particle filter 320.

Raw materials for a liquid chemical may be supplied to the liquid chemical supply tank 110 through at least one raw material supply pipe (not shown) connected from the outside of the liquid chemical recycle system 10. According to an embodiment, the liquid chemical may be a fluoric peroxide mixture (FPM) that is a high-concentration hydrofluoric acid compound.

The raw materials supplied to the liquid chemical supply tank 110 may include hydrogen fluoride (HF), hydrogen peroxide (H₂O₂), and deionized water (DIW). According to an embodiment, a mixing ratio of the raw materials may correspond to HF:H₂O₂:DIW=6.5:3:18. A liquid chemical including hydrogen fluoride may be an essential chemical material that needs to be used to etch an oxide film formed on a substrate or remove metal contamination that affects product characteristics during a semiconductor substrate process. However, in the process of supplying and using hydrogen fluoride, there is a risk of hydrogen fluoride being exposed to the outside, and even after used, hydrogen fluoride may be discharged through a complicated chemical waste water processing process. Therefore, aspects of the inventive concept are directed to an FPM liquid chemical recycle system for reducing the amount of hydrogen fluoride used and presenting optimized FPM process conditions.

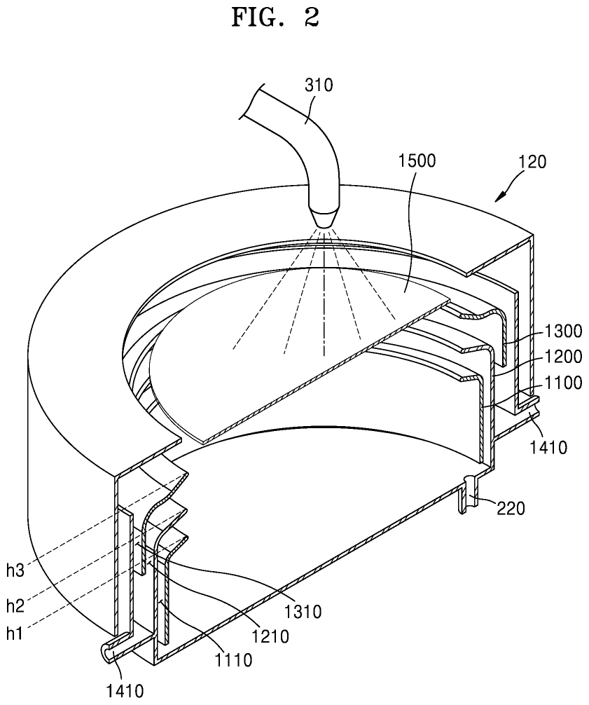

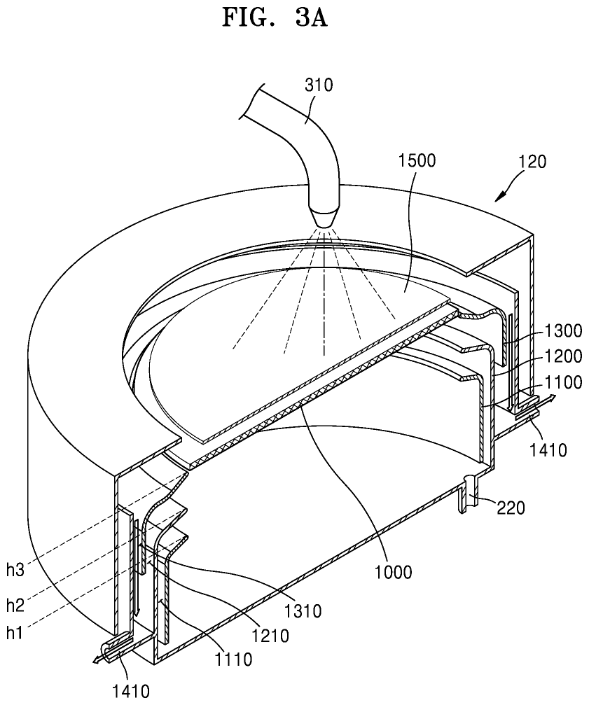

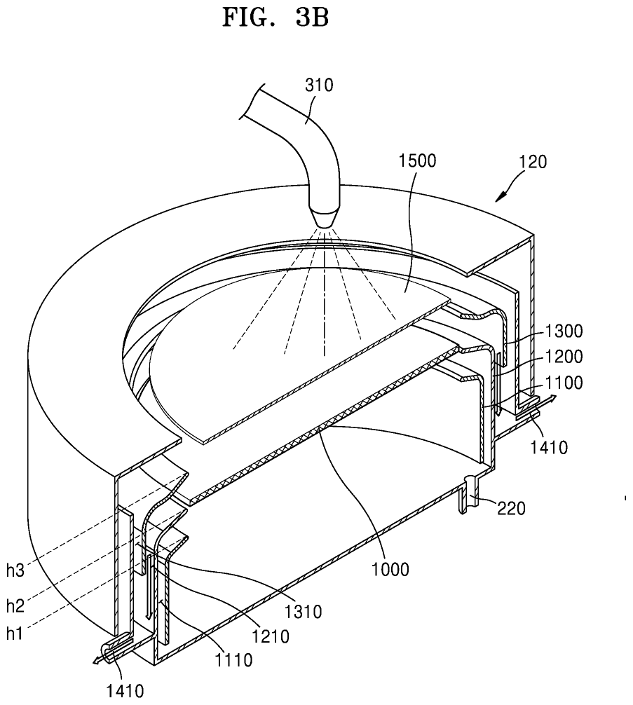

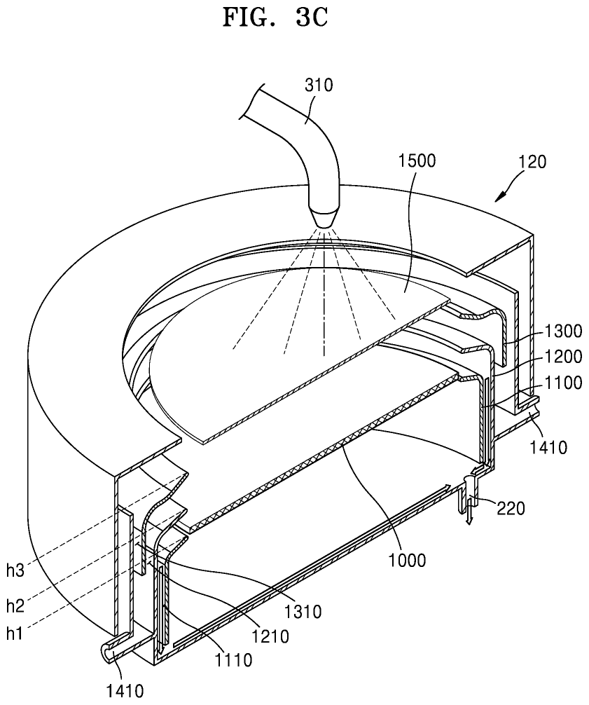

The processing tank 120 may perform a function of etching a substrate (not shown) disposed on a substrate support 1500 (see FIG. 2). The processing tank 120 may provide a space for processing a substrate therein. Liquid chemicals stored in the liquid chemical supply tank 110 may be supplied along the liquid chemical supply pipe 210 and then injected into the processing tank 120 through the injection nozzle 310. The processing tank 120 may correspond to a single wafer type substrate processing device. A detailed configuration and operation principle of the inside of the processing tank 120 is described below with reference to FIGS. 2 and 3A to 3C.

The recycle tank 130 may serve to store at least some of the remaining liquid chemicals injected into the processing tank 120 through the injection nozzle 310 subsequent to an etching of the substrate. The remaining liquid chemicals may be supplied to the recycle tank 130 along the recovery line 220. In an embodiment, the maximum remaining liquid chemicals that may be stored in the recycle tank 130 may be approximately 70 L. In an embodiment, the remaining liquid chemicals collected in the recycle tank 130 may be used up to about 1500 times to perform etching in the processing tank 120.

The remaining liquid chemicals stored in the recycle tank 130 may be supplied back to the injection nozzle 310 along the circulation line 230. In this process, an operation of filtering the liquid chemical by the particle filter 320 may be added to prevent reverse contamination due to recycle of the liquid chemical and to filter contaminants remaining in the liquid chemical.

Although not shown in the drawing, in some embodiments, the liquid chemical supply tank 110 or the recycle tank 130 may include a pump for circulating the liquid chemical stored therein. Although not shown in the drawings, in some embodiments, a supply pump for facilitating supply of the liquid chemical by pumping the liquid chemical may be additionally provided in the liquid chemical supply pipe 210 or the circulation line 230.

FIG. 2 is a cross-sectional view showing an internal configuration of the processing tank 120 shown in FIG. 1.

Referring to FIG. 2, liquid chemicals stored in the liquid chemical supply tank 110 (see FIG. 1) may be injected into the processing tank 120 along the injection nozzle 310. The substrate support 1500 may be disposed in a direction parallel to the X-axis inside the processing tank 120.

A third bowl 1300 including a ring-shaped sidewall formed in a direction parallel to a side surface of the processing tank 120 may be disposed inside the processing tank 120. A second bowl 1200 including a ring-shaped sidewall formed in a direction parallel to a side surface of the third bowl 1300 may be disposed inside the third bowl 1300. A first bowl 1100 including a ring-shaped sidewall formed in a direction parallel to a side surface of the second bowl 1200 may be disposed inside the second bowl 1200.

The first bowl 1100, the second bowl 1200, and the third bowl 1300 may have different sizes but substantially have the same shape. The shapes of the first, second, and third bowls 1100, 1200, and 1300 are the same in FIG. 2, but aspects of the inventive concept are not limited thereto. The first bowl 1100, the second bowl 1200, and the third bowl 1300 may form a three-stage bowl structure.

The uppermost surfaces of the first bowl 1100, the second bowl 1200, and the third bowl 1300 may be spaced apart from each other in a direction parallel to the substrate support 1500. A height of the uppermost surface of the first bowl 1100 may be defined as a first height h1, a height of the uppermost surface of the second bowl 1200 may be defined as a second height h2, and a height of the uppermost surface of the third bowl 1300 may be defined as a third height h3. With respect to the Z-axis direction, the first height h1 may be at a level lower than the second height h2, and the second height h2 may be at a level lower than the third height h3. The third height h3 may be at a level lower than a height of the substrate support 1500.

In some embodiments, a vertical level difference between the first height h1 and the second height h2 may be equal to a vertical level difference between the second height h2 and the third height h3. In some embodiments, the vertical level difference between the first height h1 and the second height h2 may be different from the vertical level difference between the second height h2 and the third height h3.

A first pipe 1110 may be connected along an outer circumference of the first bowl 1100 and extend vertically downward. A second pipe 1210 may be connected along an outer circumference of the second bowl 1200 and extend vertically downward. A third pipe 1310 may be connected along an outer circumference of the third bowl 1300 and extend vertically downward.

The first pipe 1110 may extend vertically downward and be integrally connected to the recovery line 220. The second pipe 1210 and the third pipe 1310 may extend vertically downward and integrally extend (i.e., connect) with a liquid chemical discharge pipe 1410 connected to a discharge unit (not shown). A role and function of each of the first to third bowls 1100, 1200, and 1300 and the first to third pipes 1110, 1210, and 1310 disposed inside the processing tank 120 are described below with reference to FIGS. 3A to 3C.

FIGS. 3A to 3C are diagrams schematically showing the principle of operation of a three-stage bowl disposed inside a processing tank.

Referring to FIGS. 3A to 3C, a pedestal 1000 may move up and down in the Z-axis direction inside the processing tank 120. The pedestal 1000 may be formed flat in the X-axis direction. The pedestal 1000 may serve to support the remaining liquid chemical flowing down the substrate support 1500 after processing a substrate (not shown) disposed on the substrate support 1500. FIGS. 3A, 3B, and 3C correspond to cases in which the pedestal 1000 is located at the third height h3, the second height h2, and the first height h1, respectively.

The pedestal 1000 may be moved by an on command and an off command (i.e., on/off command) from a controller (not shown). When the controller provides the off command, the pedestal 1000 may not move and, as such, the pedestal 1000 may remain fixed (i.e., standby) at it is current height. Subsequently, when the controller provides the on command, the pedestal 1000 may move in the vertical direction (e.g., up or down depending on its current height). For example, when the etching process is initiated, the pedestal 1000 may be located at the third height h3 and remain fixed (i.e., standby) at the third height h3 as a result of the off command being provided to the pedestal 1000 from the controller (see FIG. 3A). When the controller provides the on command to the pedestal 1000, the pedestal 1000 may move from the third height h3 (see FIG. 3A) to the first height h1 (see FIG. 3C) via the second height h2 (see FIG. 3B).

After providing the off command to the pedestal 1000, the controller may standby (i.e., wait) for a certain (i.e., predetermined) time and then provide the on command to the pedestal 1000. In the case of applying a recycle system according to aspects of the inventive concept, a liquid chemical initially introduced after having finished an etching process may have a high degree of contamination due to a high concentration of copper (Cu) ions. Therefore, as the standby time of the pedestal 1000 at the third height h3 by the off command of the controller increases, a degree of contamination of a liquid chemical to be recycled may decrease, but when the standby time excessively increases, the amount of discarded liquid chemical increases, and thus, the process efficiency may be reduced. Conversely, as the standby time of the pedestal 1000 at the third height h3 by the off command of the controller decreases, the amount of discarded liquid chemicals decreases, but the degree of contamination of the liquid chemical to be recycled increases, and thus, the process reliability may be reduced. Therefore, to balance the process efficiency with the process reliability, the controller needs to provide the on command after an appropriate time has elapsed.

In an embodiment, the appropriate time may correspond to approximately 5 seconds, but aspects of the inventive concept are not limited thereto. In some embodiments, it may take approximately 0.1 seconds for the height of the pedestal 1000 to move from the third height h3 to the first height h1 through the second height h2 by a command of the controller.

Referring back to FIG. 3A, while the pedestal 1000 is at standby at the third height h3 by the off command of the controller, the liquid chemical that has finished the etching process may flow along the pedestal 1000 and an outer circumference of the third bowl 1300 and then flow into the third pipe 1310 connected to the outer circumference of the third bowl 1300 and extending vertically downward.

The third pipe 1310 integrally extends (i.e., connects) with the liquid chemical discharge pipe 1410 together with the second pipe 1210, and the liquid chemical flowing along the third pipe 1310 may be discharged to a discharge unit along the liquid chemical discharge pipe 1410 and discarded as waste water.

FIG. 3B shows a moment when the pedestal 1000 is located at the second height h2 in a process of moving the pedestal 1000 from the third height h3 to the first height h1 by the on command of the controller. Similar to FIG. 3A, while the pedestal 1000 is located at the second height h2, the liquid chemical that has finished the etching process may flow along the pedestal 1000 and an outer circumference of the second bowl 1200 and then flow into the second pipe 1210 connected to the outer circumference of the second bowl 1200 and extending vertically downward.

The second pipe 1210 extends (i.e., connects) integrally with the liquid chemical discharge pipe 1410 together with the third pipe 1310, and thus, the liquid chemical flowing along the second pipe 1210 may be discharged to the discharge unit along the liquid chemical discharge pipe 1410 and discarded as waste water.

FIG. 3C corresponds to the pedestal 1000 that has moved to the first height h1 by the on command of the controller. The liquid chemical that has finished the etching process may flow along the pedestal 1000 and an outer circumference of the first bowl 1100 and then flow into the first pipe 1110 connected to the outer circumference of the first bowl 1100 and extending vertically downward.

The first pipe 1110 may extend vertically downward and be integrally connected to the recovery line 220. That is, the liquid chemical flowing along the first pipe 1110 may return to the recycle tank 130 through the recovery line 220 and stored in the recycle tank 130.

For example, whether the liquid chemical is recycled may be set to be distinguished by differentiating a drainage pipe according to the position relationship between each of the first to third bowls 1100, 1200, and 1300 and the pedestal 1000 inside the processing tank 120. When the pedestal 1000 is disposed at a level greater than or equal to the second height h2, the liquid chemical used in the processing tank 120 may be discarded (i.e., discharged to the discharge unit) via the discharge pipe 1410. When the pedestal 1000 is disposed at a level less than the second height h2, the liquid chemical used in the processing tank 120 may be transported to the recycle tank 130 via recovery line 220.

The position of the pedestal 1000 may be controlled by a recipe (i.e., process) preset by a user, and a desired amount of liquid chemicals may be optimized to be recovered or drained as waste water according to process conditions.

The controller is, for example, a computer, and may include, for example, a microcomputer having a central processing unit (CPU), read only memory (ROM), random access memory (RAM), input/output ports, etc. or various circuits. The controller has a computer-readable storage medium. The storage medium may store programs for controlling various processes executed in the liquid chemical recycle system 10.

The controller may control an operation of the liquid chemical recycle system 10 by allowing the CPU to execute the program stored in the storage medium by using the ROM as a work region. In addition, the program may be stored in the computer-readable storage medium, and may be installed in the storage medium of the controller from another storage medium.

The computer-readable storage medium includes, for example, a hard disk (HD), a flexible disk (FD), a compact disk (CD), a magneto-optical disk (MO), a memory card, etc.

In some embodiments, as the recovery line 220 is disposed downward toward the recycle tank 130, the liquid chemical may be easily supplied to the recycle tank 130 by gravity. Alternatively, a supply pump facilitating the supply of the liquid chemical by pumping the recovered liquid chemical may be additionally provided in the recovery line 220.

The liquid chemical recycle system 10 according to aspects of the inventive concept may further include an inspection unit (not shown) monitoring the concentration of copper (Cu) ions in the liquid chemical stored in the recycle tank 130. A recycled liquid chemical obtained by using the liquid chemical recycle system 10 according to some embodiments may be required to verify the performance or quality thereof unlike a new liquid chemical. Therefore, the liquid chemical recycle system 10 according to some embodiments may additionally include the inspection unit to discharge an initial liquid chemical having a high contamination concentration to the discharge unit through the second pipe 1210, the third pipe 1310 and the liquid chemical discharge pipe 1410 and then, inspect whether the recycled liquid chemical supplied through the first pipe 1110 and the recovery line 220 is recyclable.

In addition, the inspection unit may be provided to inspect whether a liquid chemical accommodated in the liquid chemical supply tank 110 is recyclable, and whether both the liquid chemical accommodated in the liquid chemical supply tank 110 and a liquid chemical accommodated in the recycle tank 130 are recyclable.

And, as a result of the inspection by the inspection unit, when the liquid chemical is recyclable, the recycled liquid chemical may be supplied to the injection nozzle 310. However, as a result of the inspection by the inspection unit, when the liquid chemical is non-recyclable, a non-recyclable liquid chemical needs to be discharged to the outside along the discharge unit.

Thus, the liquid chemical recycle system 10 according to some embodiments may further include the discharge unit discharging the non-recyclable liquid chemical to the outside. When the inspection unit is provided to inspect whether the liquid chemical accommodated in the recycle tank 130 is recyclable, the discharge unit may be connected to a rear end of the recycle tank 130. When the inspection unit is provided to inspect whether the liquid chemical accommodated in the liquid chemical supply tank 110 is recyclable, the discharge unit may be provided to discharge the liquid chemical accommodated in the liquid chemical supply tank 110.

As described above, the liquid chemical recycle system 10 according to some embodiments may additionally include the inspection unit and the discharge unit to more stably use the recycled liquid chemical. Therefore, the liquid chemical recycle system 10 according to some embodiments may recycle a liquid chemical having a low degree of contamination among liquid chemicals used without discarding the liquid chemical, thereby minimizing the consumption of an expensive liquid chemical.

In addition, the recycle tank 130 included in the liquid chemical recycle system 10 according to aspects of the inventive concept may have its own circulation system that filters particles, etc. by itself. As a result, the liquid chemical recycle system 10 according to aspects of the inventive concept may filter copper ions or other impurities included in the recycled liquid chemical, thereby enhancing the reliability of the recycled liquid chemical.

A liquid chemical supply system according to aspects of the inventive concept may include a liquid chemical supply tank storing and supplying a liquid chemical, a processing tank processing an etching process on a substrate disposed on a substrate support, a pedestal disposed in parallel to the substrate support at a level lower than the substrate support inside the processing tank, a recycle tank storing a remaining liquid chemical and filtering impurities through an internal circulation system, and a circulation line connecting the recycle tank to the processing tank, in which the remaining liquid chemical that has finished filtering may be discharged to a recovery line through a first pipe and re-supplied to the processing tank, which may be substantially the same as the liquid chemical recycle system 10 described above.

A method of manufacturing a semiconductor device according to aspects of the inventive concept may include providing a substrate including a first thin film and removing at least a part of the first thin film by using a wet etching process on the substrate, the wet etching process may include a liquid chemical recycle system, the liquid chemical recycle system may include a liquid chemical supply tank storing and supplying a liquid chemical, a processing tank receiving the liquid chemical supplied from the liquid chemical supply tank through an injection nozzle and performing an etching process on the substrate disposed on a substrate support, a recovery line recovering the liquid chemical discharged from the processing tank, a recycle tank connected to the recovery line and filtering impurities through its own circulation system, and a circulation line connecting the recycle tank to the injection nozzle, and the processing tank may include a third bowl including a ring-shaped sidewall formed in a direction parallel to a side surface of the processing tank inside the processing tank, a second bowl including a ring-shaped side wall formed in a direction parallel to a side surface of the third bowl inside the third bowl, and a first bowl including a ring-shaped side wall formed in a direction parallel to a side surface of the second bowl in the second bowl. Also, the liquid chemical recycle system used in the method of manufacturing the semiconductor device described above may be substantially the same as the liquid chemical recycle system 10 described above. In an embodiment, the first thin film may be an oxide film to be etched. In an embodiment, the first thin film may correspond to a film including metal contamination that affects product characteristics.

An operation procedure of the liquid chemical recycle system used in the method of manufacturing the semiconductor device may be understood with reference to FIGS. 1, 2, and 4.

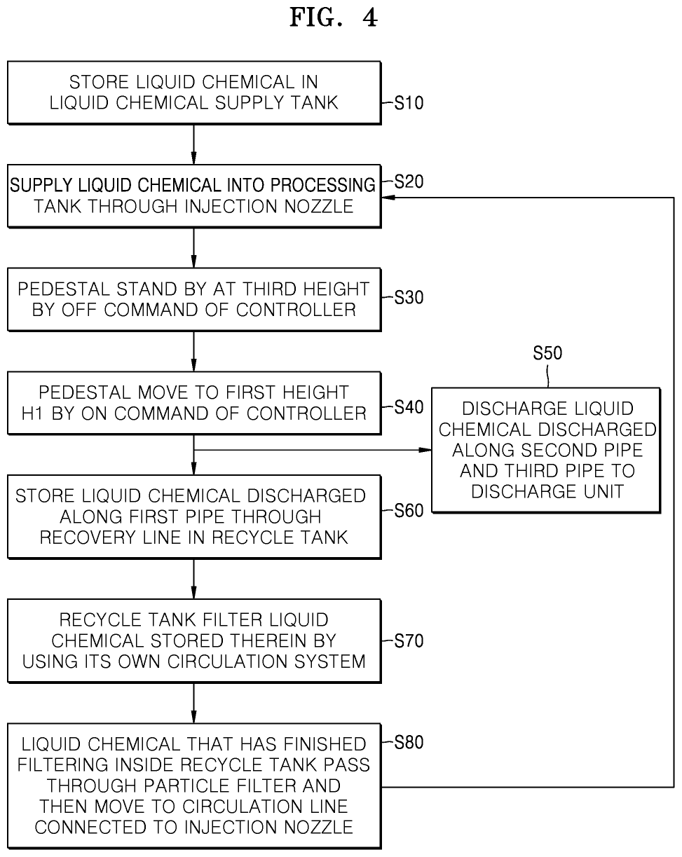

Referring to FIG. 4 together with FIGS. 1 and 2, the liquid chemical is stored in the liquid chemical supply tank 110 (S10), and the stored liquid chemical is supplied into the processing tank 120 through the injection nozzle 310 (S20). At this time, the liquid chemical stored in the liquid chemical supply tank 110 may correspond to a liquid chemical in which hydrogen fluoride (HF), hydrogen peroxide (H₂O₂), and deionized water (DIW) are mixed at a ratio of 6.5:3:18.

The pedestal 1000 may standby at the third height h3 by an off command of a controller (S30), receive an on command of the controller after a certain (i.e., predetermined) time elapsed since providing the off command, and move to the first height h1 through the second height h2 (S40). The certain time may correspond to, for example, approximately 5 seconds.

In this process, while the pedestal 1000 is at standby at the third height h3, the liquid chemical supplied into the processing tank 120 may flow along the pedestal 1000 and an outer circumference of the third bowl 1300, and then flow into the third pipe 1310 connected to the outer circumference of the third bowl 1300 and extending vertically downward.

While the pedestal 1000 passes the second height h2, the liquid chemical supplied into the processing tank 120 may flow along the pedestal 1000 and an outer circumference of the second bowl 1200 and then flow into the second pipe 1210 connected to the outer circumference of the second bowl 1200 and extending vertically downward. For example, when the pedestal 1000 is disposed at a level greater than or equal to the second height h2, the liquid chemical supplied into the processing tank 120 may flow along the pedestal 1000 and one of the outer circumferences of the third bowl 1300 and the second bowl 1200, and then flow into one of the third pipe 1310 and the second pipe 1210. A level at which the pedestal 1000 is disposed above the third height h3 may be limited by the level at which the substrate support 1500 is disposed. For example, a level at which the pedestal 1000 is disposed above the third height h3, may not be the same or greater than the level at which the substrate support 1500 is disposed.

The second pipe 1210 and the third pipe 1310 extend (i.e., connect) integrally with the liquid chemical discharge pipe 1410 together, and thus, the liquid chemical flowing along the second pipe 1210 and the third pipe 1310 may be discharged to a discharge unit along the liquid chemical discharge pipe 1410 (S50) and discarded as waste water

When the pedestal 1000 moves to the first height h1, the liquid chemical supplied into the processing tank 120 may flow along the pedestal 1000 and an outer circumference of the first bowl 1100 and then flow into the first pipe 1110 connected to the outer circumference of the first bowl 1100 and extending vertically downward. For example, when the pedestal 1000 is disposed at a level less than the second height h2, the liquid chemical supplied into the processing tank 120 may flow along the pedestal 1000 and an outer circumference of the first bowl 1100, and then flow into the first pipe 1110 connected to the outer circumference of the first bowl 1100 and extending vertically downward.

The first pipe 1110 may extend vertically downward and be integrally connected to the recovery line 220. For example, the liquid chemical flowing along the first pipe 1110 may return to the recycle tank 130 through the recovery line 220 and stored in the recycle tank 130 (S60).

The recycle tank 130 may filter the liquid chemical supplied from the recovery line 220 by using its own circulation system (S70). The circulation system may be used to filter particles remaining in the liquid chemical, and as a result, copper ions or other impurities included in the recycled liquid chemical are filtered, thereby enhancing the reliability of the recycled liquid chemical.

Thereafter, the liquid chemical that has finished filtering inside the recycle tank 130 may pass through the particle filter 320 and then move to the circulation line 230 connected to the injection nozzle 310 (S80). The particle filter 320 may perform a function of removing contaminants remaining in the recycled liquid chemical.

The liquid chemical moved along the circulation line 230 may be again supplied into the processing tank 120 through the injection nozzle 310 (S20), and a high-concentration hydrofluoric acid liquid chemical may be repeatedly recycled by repeating the above circulation process.

The liquid chemical recycle system 10 described above may be effectively utilized in an FPM process. The FPM process may be performed to remove copper (Cu) ions remaining on the back side of a substrate and to remove a portion or quantity of film on the back side of the substrate before proceeding with a photo process. Among materials included in the FPM liquid chemical, hydrogen fluoride may be used to remove an oxide film and copper (Cu), and hydrogen peroxide may be used to prevent reverse adsorption of copper (Cu) ions. The FPM process may correspond to a process necessarily used to produce a semiconductor product.

According to aspects of the inventive concept, a liquid chemical is selectively recycled by utilizing a three-stage bowl structure that may easily distinguish between a recycle path and a discharge path of the FPM liquid chemical, and thus, even though the liquid chemical is recycled, a risk of reverse contamination of the substrate due to copper (Cu) ions may be reduced, and simultaneously the amount of liquid chemicals used may be reduced. Therefore, aspects of the inventive concept may reduce the cost of materials, which are raw materials of the liquid chemical, and also reduce the amount of waste water and carbon emissions associated with an FPM process used to produce a semiconductor product. In addition, the risk of reverse contamination described above may be further prevented owing to the internal circulation and filtering system of the recycle tank.

While aspects of the inventive concept have been particularly shown and described with reference to embodiments thereof, it will be understood that various changes in form and details may be made therein without departing from the spirit and scope of the following claims.

What is claimed is:

1. A liquid chemical recycle system comprising:
a liquid chemical supply tank storing and configured to supply a liquid chemical;
a processing tank configured to inject the liquid chemical supplied from the liquid chemical supply tank through an injection nozzle to perform an etching process on a substrate disposed on a substrate support;
a recovery line configured to recover the liquid chemical discharged from the processing tank;
a recycle tank connected to the recovery line; and
a circulation line configured to connect the recycle tank to the injection nozzle,
wherein the processing tank comprises
a third bowl comprising a ring-shaped side wall formed in a direction parallel to a side surface of the processing tank inside the processing tank;
a second bowl comprising a ring-shaped side wall formed in a direction parallel to a side surface of the third bowl inside the third bowl; and
a first bowl comprising a ring-shaped side wall formed in a direction parallel to a side surface of the second bowl inside the second bowl.

2. The liquid chemical recycle system of claim 1, further comprising:
a pedestal configured to reciprocate in a vertical direction between a first height, which is a height of an uppermost surface of the first bowl, a second height, which is a height of an uppermost surface of the second bowl, and a third height, which is a height of an uppermost surface of the third bowl; and
a controller configured to provide an on command and an off command to the pedestal,
wherein the substrate support is disposed at a level higher than the third height.

3. The liquid chemical recycle system of claim 2, wherein
the pedestal is configured to standby at the third height when the etching process is initiated, and
move to the first height when the controller provides the on command.

4. The liquid chemical recycle system of claim 2, wherein the controller is configured to provide the on command to the pedestal after a predetermined time has elapsed since providing the off command to the pedestal.

5. The liquid chemical recycle system of claim 4, wherein the predetermined time is 5 seconds or more.

6. The liquid chemical recycle system of claim 1, further comprising:
a third pipe connected along an outer circumference of the third bowl and extending vertically downward;
a second pipe connected along an outer circumference of the second bowl and extending vertically downward; and
a first pipe connected along an outer circumference of the first bowl and extending vertically downward.

7. The liquid chemical recycle system of claim 6, wherein
the third pipe and the second pipe are connected to a discharge unit, and
the first pipe is connected to the recovery line.

8. The liquid chemical recycle system of claim 1, wherein a raw material supplied to the liquid chemical supply tank includes hydrogen fluoride (HF), hydrogen peroxide (H₂O₂), and deionized water (DIW).

9. The liquid chemical recycle system of claim 1, further comprising:
a particle filter disposed along the circulation line between the recycle tank and the injection nozzle; and
an inspection unit configured to monitor a concentration of copper (Cu) ions inside the liquid chemical stored in the recycle tank.

10. The liquid chemical recycle system of claim 1, wherein the recycle tank includes a circulation system to filter impurities.

11. A liquid chemical recycle system comprising:
a liquid chemical supply tank storing and configured to supply a liquid chemical;
a processing tank configured to perform an etching process on a substrate disposed on a substrate support;
a pedestal disposed in parallel to the substrate support at a level lower than the substrate support inside the processing tank;
a recycle tank storing a remaining liquid chemical discharged from the processing tank during the etching process and configured to filter impurities through an internal circulation system; and
a circulation line configured to connect the recycle tank and the processing tank,
wherein the remaining liquid chemical is discharged from the processing tank through a first pipe of the processing tank to a recovery line configured to connect the processing tank and the recycle tank and re-supplied to the processing tank through the circulation line.

12. The liquid chemical recycle system of claim 11, wherein
the processing tank includes a third bowl disposed below the substrate support, a second bowl formed inside the third bowl, and a first bowl formed inside the second bowl,
the pedestal is configured to reciprocate in a vertical direction between a first height, which is a height of an uppermost surface of the first bowl, a second height, which is a height of an uppermost surface of the second bowl, and a third height, which is a height of an uppermost surface of the third bowl inside the processing tank.

13. The liquid chemical recycle system of claim 12, wherein
the third bowl is connected to a third pipe, the second bowl is connected to a second pipe, and the first bowl is connected to the first pipe,
the third pipe and the second pipe are connected to a discharge unit, and
the first pipe is connected to the recovery line.

14. The liquid chemical recycle system of claim 12, wherein
the pedestal is configured to standby at the third height, which is the height of the uppermost surface of the third bowl, when the etching process is initiated, and
move to the first height, which is the height of the uppermost surface of the first bowl, when a controller provides an on command.

15. The liquid chemical recycle system of claim 14, wherein the controller is configured to provide the on command to the pedestal after a predetermined time has elapsed since providing an off command to the pedestal.

16. The liquid chemical recycle system of claim 11, further comprising:
a particle filter disposed along the circulation line; and
an inspection unit configured to monitor a concentration of copper (Cu) ions inside the liquid chemical stored in the recycle tank.

17. The liquid chemical recycle system of claim 11, wherein a raw material supplied to the liquid chemical supply tank includes hydrogen fluoride (HF), hydrogen peroxide (H₂O₂), and deionized water (DIW).

18. A method of manufacturing a semiconductor device, the method comprising:
providing a substrate comprising a first thin film; and
removing at least a part of the first thin film by using a wet etching process on the substrate,
wherein the wet etching process utilizes a liquid chemical recycle system,
the liquid chemical recycle system includes
a liquid chemical supply tank storing and configured to supply a liquid chemical, a processing tank configured to inject the liquid chemical supplied from the liquid chemical supply tank through an injection nozzle to perform an etching process on a substrate disposed on a substrate support, a recovery line configured to recover the liquid chemical discharged from the processing tank, a recycle tank connected to the recovery line and configured to filter impurities through a circulation system, and a circulation line configured to connect the recycle tank to the injection nozzle, and
the processing tank includes a third bowl comprising a ring-shaped side wall formed in a direction parallel to a side surface of the processing tank inside the processing tank, a second bowl comprising a ring-shaped side wall formed in a direction parallel to a side surface of the third bowl inside the third bowl, and a first bowl comprising a ring-shaped side wall formed in a direction parallel to a side surface of the second bowl inside the second bowl.

19. The method of claim 18, wherein
the liquid chemical recycle system further includes a controller,
a pedestal is configured to standby at a third height, which is a height of an uppermost surface of the third bowl, when the etching process is initiated, and move to a first height, which is a height of an uppermost surface of the first bowl, when the controller provides an on command.

20. The method of claim 18, wherein
the third bowl is connected to a third pipe, the second bowl is connected to a second pipe, and the first bowl is connected to a first pipe,
the third pipe and the second pipe are connected to a discharge unit, and
the first pipe is connected to the recovery line.
